(19) United States
(12) Patent Application Publication
(10) Pub. No.: US 2014/0179048 A1
(43) Pub. Date: Jun. 26, 2014

(54) METHOD FOR PREPARING ABSORBING LAYER OF SOLAR CELL AND THERMAL TREATMENT DEVICE THEREOF

(71) Applicant: INDUSTRIAL TECHNOLOGY RESEARCH INSTITUTE, Hsinchu (TW)

(72) Inventors: Tzung-Shin Wu, Hsinchu (TW); Shih-Hsiung Wu, Tainan (TW); Yu-Yun Wang, Hualien County (TW); Hung-Ru Hsu, Changhua County (TW); Ho-Min Chen, Taichung (TW)

(21) Appl. No.: 13/908,256

(22) Filed: Jun. 3, 2013

(30) Foreign Application Priority Data
Dec. 21, 2012 (TW) 101149186

(51) Int. Cl. H01L 31/18

(52) U.S. Cl. CPC H01L 31/18
USPC 438/57; 34/218

(57) ABSTRACT

A method for preparing an absorbing layer of a solar cell includes the following steps. An absorbing layer precursor containing at least one group XIV element is loaded on a substrate. A solid vapor source containing a group XIV element, the same as the group XIV element in the absorbing layer precursor is provided. The solid vapor source corresponds to the absorbing layer precursor. The solid vapor source and the absorbing layer precursor are kept apart by a distance. A heating process is performed so that the absorbing layer precursor forms an absorbing layer, the solid vapor source is vaporized and generates a gas containing the group XIV element, and the gas containing the group XIV element inhibits the effusion of the group XIV element of the absorbing layer precursor so that the proportion of the group XIV element in the formed absorbing layer is consistent.

### CROSS-REFERENCE TO RELATED APPLICATIONS

This non-provisional application claims priority under 35 U.S.C. §119(a) on Patent Application No(s). 101149186 filed in Taiwan, R.O.C. on Dec. 21, 2012, the entire contents of which are hereby incorporated by reference.

### TECHNICAL FIELD

The disclosure relates to a method for preparing a solar cell and a device thereof.

### BACKGROUND

With the development of technologies, the exploitation of green power has become an important issue in all fields. Solar energy, which is easily obtained, has a low contamination, being highly safe, as well as being nearly inexhaustible, and is increasingly being used in recent years for power generation.

Currently, mainstreaming solar cells adopt group XI-XIII-XVI, for example, copper-indium-selenium (CIS) or copper-indium-gallium-selenium (CIGS) as absorbing layers. However, rare elements, such as indium (In) and gallium (Ga) in the group XIII elements, are employed in the solar cells so that the production cost of the solar cell is greatly increased. Therefore, group XI-XII-XIV-XVI solar cells, for example, copper-zinc-tin-sulfur (CZTS), copper-zinc-tin-selenium (CZTSe), or copper-zinc-tin-sulfur-selenium (CZTSSe) have been used as the absorbing layer of the solar cell recently.

As for the CZTS, the crystal form of the CZTS that can be used as the absorbing layer of the solar cell is a Kesterite crystal form. The crystal form of the CZTS may vary according to the proportions of the element compositions. Therefore, during the preparation of the absorbing layer, the proportions of copper, zinc, tin, and sulfur need to be consistent so as to avoid the formation of other crystal forms. Specifically, when the element effuses from the absorbing layer during the heating process of the preparation of the solar cell, the CZTS may generate other crystal forms, for example, a Stannite crystal form of the CZTS. When other crystal forms are formed in the absorbing layer of the solar cell, the transformation efficiency of the solar cell is lowered or completely lost because of the corresponding high resistance, low carrier concentration, or the absence of the photoelectric effect of the absorbing layer of the solar cell. The Kesterite crystal form and the Stannite crystal form of the CZTS absorbing layer may co-exist or mutually transform during the preparation process, and the Stannite crystal form of the CZTS does not generate a photoelectric effect. Therefore, when the Stannite crystal form is formed in the CZTS absorbing layer, the transformation efficiency of the manufactured solar cell is lowered.

Therefore, how to design a method for preparing an absorbing layer of a solar cell and a thermal treatment device thereof so as to alleviate the problem that different crystal forms are generated due to the effusion of the element in the absorbing layer during the preparation process of the solar cell has become a problem needed to be solved.

### SUMMARY

According to an embodiment of the disclosure, a method for preparing an absorbing layer of a solar cell is provided. The method comprises the following steps. A substrate is provided. An absorbing layer precursor is loaded on the substrate. The absorbing layer comprises at least one group XIV element. A solid vapor source is provided. The solid vapor source contains a group XIV element that is the same as the group XIV element of the absorbing layer precursor. The solid vapor source corresponds to the absorbing layer precursor, as well as the solid vapor source and the absorbing layer precursor are kept apart by a distance. A heating process is performed so that the absorbing layer precursor forms an absorbing layer on the substrate as well as the solid vapor source is vaporized and generates a gas containing the group XIV element. The gas containing the group XIV element inhibits the effusion of the group XIV element of the absorbing layer precursor so that the proportion of the group XIV element in the formed absorbing layer is consistent.

According to an embodiment of the disclosure, a thermal treatment device used for performing thermal treatment on an absorbing layer precursor of a solar cell is provided. The absorbing layer precursor contains at least one group XIV element. The thermal treatment device comprises a cavity, a substrate, a base, and a solid vapor source. The substrate is disposed in the cavity, and used for bearing the absorbing layer precursor. The base is disposed in the cavity, and faces the substrate and the absorbing layer precursor. The solid vapor source is disposed on the substrate, and contains a group XIV element the same as the group XIV element of the absorbing layer precursor. The solid vapor source faces the absorbing layer precursor as well the solid vapor source and the base are kept apart by a distance, so that the solid vapor source inhibits the effusion of the group XIV element of the absorbing layer precursor so that the proportion of the group XIV element in an absorbing layer formed by the absorbing layer precursor is consistent.

### BRIEF DESCRIPTION OF THE DRAWINGS

The disclosure will become more fully understood from the detailed description given herein below for illustration only and thus does not limit the disclosure, wherein:

FIG. 1 is a schematic view of a thermal treatment device according to an embodiment of the disclosure;

FIG. 2 is a flow chart of a method for preparing an absorbing layer of a solar cell according to an embodiment of the disclosure;

FIG. 3 is a top view of the thermal treatment device in FIG. 1 before a solid vapor source is disposed; and

FIG. 4 is a top view of the thermal treatment device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

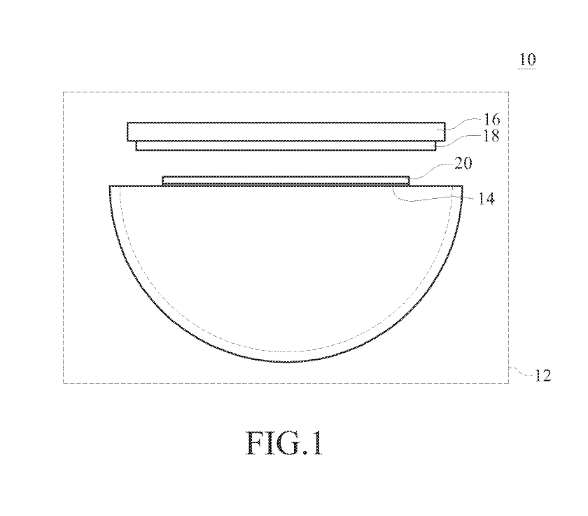

Please refer to FIG. 1, FIG. 1 is a schematic view of a thermal treatment device according to an embodiment of the disclosure.

A thermal treatment device 10 is used for performing a thermal treatment to an absorbing layer precursor 20 of a solar cell. The absorbing layer precursor 20 is, for example, an absorbing layer precursor containing a group XIV element, such as the CZTS or the CZTSe. In the following descriptions, the CZTS is described as an example of the absorbing layer precursor 20. The absorbing layer precursor 20 contains a group XIV element and a group XVI element, for example, tin and sulfur of the CZTS.

The thermal treatment device 10 comprises a cavity 12, a substrate 14, a base 16, and a solid vapor source 18. The cavity 12 is, for example, an open cavity or a half-open cavity. The cavity 12 has a non-oxygen environment so as to avoid the oxidation of the composition of the absorbing layer precursor 20 by oxygen. The cavity 12 is filled with argon and a gas containing a group XVI element, the gas containing the group XVI element is sulfur vapor, selenium vapor, hydrogen sulfide, hydrogen selenide, or the combination thereof. Therefore, the effusion of sulfur in the absorbing layer precursor 20 is inhibited. Moreover, when the absorbing layer precursor 20 is the CZTS, the gas containing the group XVI element is sulfur vapor, a mixture of sulfur vapor and selenium vapor, hydrogen sulfide, a mixture of hydrogen sulfide and hydrogen selenide, or a mixture of the gases described above. When the absorbing layer precursor 20 is the CZTSSe, the gas containing the group XVI element is a mixture of sulfur vapor and selenium vapor, a mixture of hydrogen sulfide and hydrogen selenide, or a mixture of the gases described above.

The substrate 14 is disposed in the cavity 12, and the substrate 14 is used for bearing the absorbing layer precursor 20. The substrate 14 is, for example, made of a high-temperature resistant material, such as titanium, platinum, ceramic, or quartz, so as to avoid the deterioration of the substrate 14 under a high temperature during the preparation of the absorbing layer of the solar cell.

The base 16 is disposed in the cavity 12, as well as the base 16 faces the substrate 14 and the absorbing layer precursor 20. The solid vapor source 18 is disposed on the base 16, and the solid vapor source 18 contains a group XIV element (for example, tin) and a group XVI element (for example, sulfur) the same as the group XIV element and the group XVI element of the absorbing layer precursor 20. The solid vapor source 18 is stannic sulfide, stannous sulfide, stannic selenide, stannous selenide, or the combination thereof. For example, the solid vapor source 18 is a mixture of stannic sulfide, stannic selenide, and stannous selenide, a mixture of stannic sulfide and stannic selenide, or a mixture of the above compositions. In the embodiment of the disclosure, the adopted group XVI element is a group XVI element except oxygen, for example, sulfur or selenium. The solid vapor source 18 is disposed on the base 16, and is loaded on the base 16 through coating, chemical plating, sputtering, or evaporation. The solid vapor source 18 faces the absorbing layer precursor 20, as well the substrate 14 and the solid vapor source 18 are kept apart by a distance, so that the solid vapor source 18 inhibits the effusion of tin in the absorbing layer precursor 20 so that the proportion of tin in an absorbing layer formed by the absorbing layer precursor 20 is consistent. When the distance between the solid vapor source 18 and the absorbing layer precursor 20 is shorter, the inhibition of the effusion of tin of the absorbing layer precursor 20 by the solid vapor source 18 is better and the proportion of tin in the absorbing layer is more consistent, as well as the element distribution on the absorbing layer is more uniform. However, when the solid vapor source 18 attaches to the absorbing layer precursor 20, the solid vapor source 18 weakens the structure of the absorbing layer formed by the absorbing layer precursor 20, so that the manufactured solar cell is undesirable. In an embodiment, the distance between the solid vapor source 18 and the absorbing layer precursor 20 is between 0.1 centimeters (cm) and 4 cm. In some other embodiments, the distance between the solid vapor source 18 and the absorbing layer precursor 20 is between 0.1 cm and 2 cm.

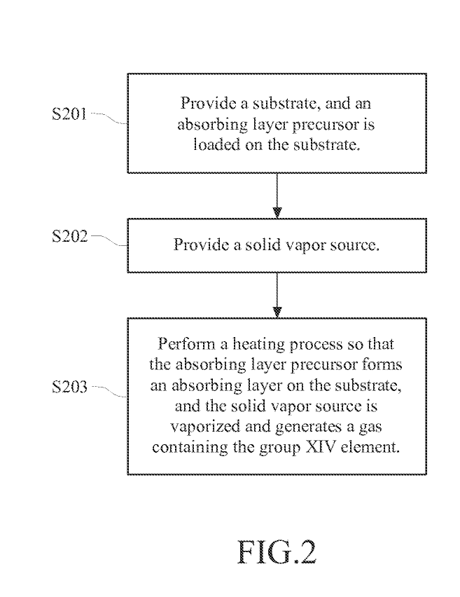

Please refer to FIG. 2, FIG. 2 is a flow chart of a method for preparing an absorbing layer of a solar cell according to an embodiment of the disclosure.

First, provide a substrate, and an absorbing layer precursor is loaded on the substrate (Step S201). The material of the substrate is, for example, titanium, platinum, ceramics, or quartz, so as to avoid the deterioration of the substrate under a high temperature during the preparation of the absorbing layer of the solar cell. The absorbing layer precursor comprises at least one group XIV element and a group XVI element, for example, tin and sulfur of the CZTS.

Then, provide a solid vapor source (Step S202). The solid vapor source contains a group XIV element and a group XVI element, which are the same group XIV element and the same group XVI element as the absorbing layer precursor, for example, tin and sulfur. The solid vapor source faces and corresponds to the absorbing layer precursor, as well the solid vapor source and the absorbing layer precursor are kept apart by a distance. In an embodiment, the distance between the solid vapor source and the absorbing layer precursor is between 0.1 cm and 4 cm. In some other embodiments, the distance between the solid vapor source and the absorbing layer precursor is between 0.1 cm and 2 cm.

Afterwards, perform a heating process so that the absorbing layer precursor forms an absorbing layer on the substrate, and the solid vapor source is vaporized and generates a gas containing the group XIV element (Step S203), for example, a gas of tin compound. Moreover, the solid vapor source generates a gas consisting the group XIV element and the group XVI element, for example, stannic sulfide, stannic selenide, stannous sulfide, stannous selenide, or the combination thereof In an embodiment, the reaction temperature of the heating process is between 200° C. and 800° C., and the heating time is between 20 minutes and 3 hours. In some other embodiments, the reaction temperature of the heating process is between 350° C. and 650° C., and the heating time is between 30 minutes and 2 hours. The substrate is inert under the reaction temperature so that the substrate is not deteriorated and further affects the composition of the absorbing layer precursor.

During the heating process, the solid vapor source is vaporized and generates a gas of tin compound, and a dynamic equilibrium is achieved between the gaseous phase and the solid phase of the tin compound. Therefore, when the tin compound in the absorbing layer precursor effuses, the gas of the tin compound compensates for the effusion of the tin compound of the absorbing layer precursor, so that the effusion of the tin compound from the absorbing layer precursor is inhibited, and the proportion of tin in the formed absorbing layer is consistent. Since the proportion of tin in the absorbing layer is consistent, the absorbing layer remains to be a single Kesterite crystal form.

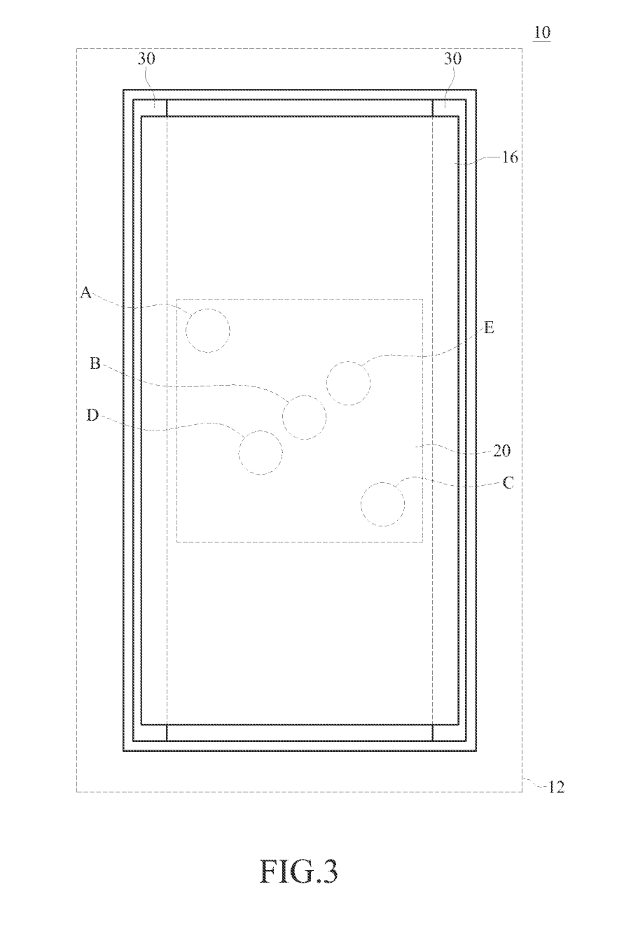

Please refer to FIG. 1 to FIG. 3, FIG. 3 is a top view of the thermal treatment device in FIG. 1 before a solid vapor source is disposed. The variation of the element composition in the absorbing layer before a solid vapor source is disposed is illustrated by the following comparisons.

According to Step S201, an absorbing layer precursor 20 is loaded on the substrate 14. The size of the absorbing layer precursor 20 is 8 cm×8 cm, and the mole percentage of the element composition of the absorbing layer precursor 20 is as the following table.

| | | | | | Copper/ | |
|---|---|---|---|---|---|---|
| Element | Copper | Zinc | Tin | Sulfur | (Zinc + Tin) | Zinc/Tin |
| Percentage | 22.13 | 15.22 | 13.41 | 49.24 | 0.77 | 1.14 |
| (%) | | | | | | |

Afterwards, tin sulfide powder is disposed on the two sides 30 of the substrate 14 so as to provide a source of a gas containing the group XVI element. An absorbing layer is prepared according to Step S203, wherein the reaction temperature is 500° C. and the reaction time is 1 hour.

Finally, a test is performed on areas A to E in FIG. 3 so as to analyze the element compositions in the areas A to E in the absorbing layer. The results of the test are as the following table.

| | | | | | Copper/ | |
|---|---|---|---|---|---|---|
| | Copper | Zinc | Tin | Sulfur | (Zinc + Tin) | Zinc/Tin |
| A | 21.35 | 15.62 | 13.70 | 49.33 | 0.73 | 1.14 |
| B | 27.11 | 17.06 | 11.33 | 44.50 | 0.95 | 1.51 |
| C | 22.01 | 15.31 | 13.72 | 48.96 | 0.76 | 1.12 |
| D | 26.11 | 17.11 | 13.61 | 43.17 | 0.85 | 1.26 |
| E | 24.79 | 16.82 | 13.05 | 45.34 | 0.83 | 1.29 |

The element compositions in the areas A to E are compared with the element compositions before the heating process is performed. The ratio of zinc/tin in the area A is 1.14, the ratio of zinc/tin in the area B is 1.51, the ratio of zinc/tin in the area C is 1.12, the ratio of zinc/tin in the area D is 1.26, and the ratio of zinc/tin in the area E is 1.29. The ratios of zinc/tin in the areas A and C are in the range of 1.14 with 3% margin of error, that is, between 1.11 and 1.17.

When the ratio of zinc/tin is between 1.05 and 1.2, the formed absorbing layer is mainly a single Kesterite crystal form. When the ratio of zinc/tin is beyond this range, other crystal forms are formed in the absorbing layer, as well as the performance of the solar cell is lowered. In the areas B, D, and E, since tin effuses from the absorbing layer precursor 20 during the heating process, the proportion of tin in the formed absorbing layer is reduced, so that the ratio of zinc/tin is increased and other crystal forms are formed, as well the performance of the solar cell is lowered. In addition, since the ratio of zinc/tin in the areas A to E are apparently different from each other, the element distribution in the areas A to E is not uniform, and the transformation efficiency of the manufactured solar cell is worse.

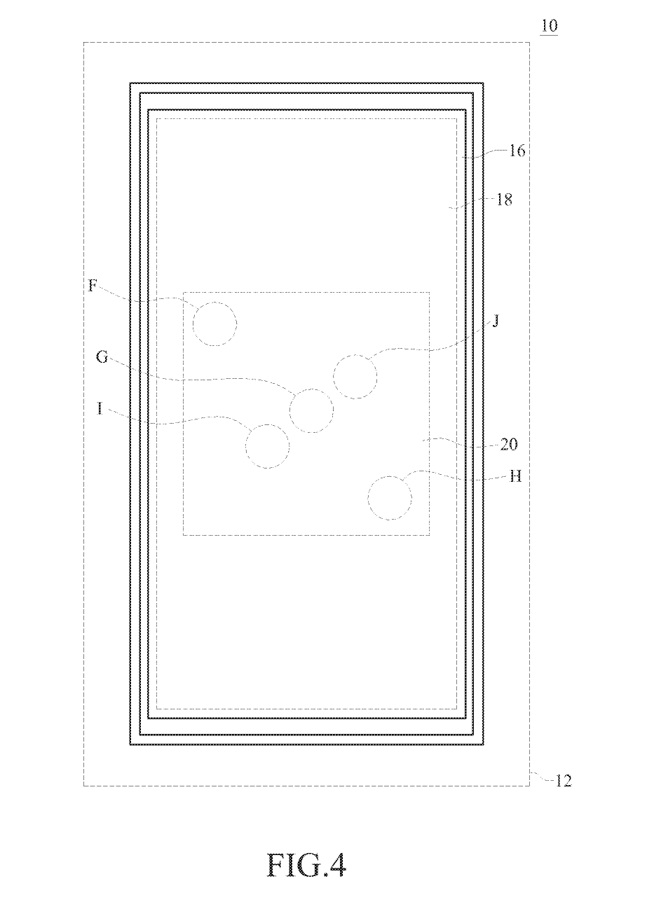

Afterwards, please refer to FIG. 1, FIG. 2, and FIG. 4, FIG. 4 is a top view of the thermal treatment device in FIG. 1. The variation of the element composition in the absorbing layer after a solid vapor source is disposed is illustrated below.

First, an absorbing layer precursor 20 is loaded on the substrate 14 according to Step S201. The size of the absorbing layer precursor 20 is 8 cm×8 cm, and the element composition of the absorbing layer precursor 20 is as the following table.

| | | | | | Copper/ | |
|---|---|---|---|---|---|---|
| Element | Copper | Zinc | Tin | Sulfur | (Zinc + Tin) | Zinc/Tin |
| Percentage | 22.13 | 15.22 | 13.41 | 49.24 | 0.77 | 1.14 |
| (%) | | | | | | |

Then, according to Step S202, a solid vapor source 18 is provided and disposed on the base 16, as well argon and sulfur vapor are provided so as to serve as the source of the gas containing the group XVI element. Further, according to Step S203, an absorbing layer is prepared. The distance between the solid vapor source 18 and the absorbing layer precursor 20 is 0.5 cm, the reaction temperature is 500° C., and the reaction time is 1 hour.

Finally, a test is performed on areas F to J in FIG. 4 so as to analyze the element compositions in the areas F to J in the absorbing layer. The results of the test are as the following table.

| | | | | | Copper/ | |
|---|---|---|---|---|---|---|
| | Copper | Zinc | Tin | Sulfur | (Zinc + Tin) | Zinc/Tin |
| F | 21.85 | 14.98 | 12.81 | 50.36 | 0.78 | 1.17 |
| G | 21.56 | 15.06 | 13.11 | 50.27 | 0.77 | 1.15 |
| H | 22.13 | 14.73 | 13.35 | 49.79 | 0.79 | 1.10 |
| I | 23.01 | 16.06 | 14.29 | 46.64 | 0.76 | 1.12 |
| J | 21.08 | 15.11 | 13.26 | 50.55 | 0.74 | 1.14 |

The element compositions in the areas F to J are compared with the element compositions after the heating process is performed. The ratios of zinc/tin in the areas F to J are between 1.05 and 1.2, so that the proportion of tin in the absorbing layer is consistent, and other crystal forms are not generated in the absorbing layer. In addition, since the differences between the ratios of zinc/tin in the areas F to J are not apparent, the element distribution in the areas F to J is uniform, and the transformation efficiency of the manufactured solar cell is better.

In these embodiments, the solid vapor source 18 inhibits the effusion of tin from the absorbing layer precursor 20, and the proportion of tin of the solid vapor source 18 in the absorbing layer formed by the absorbing layer precursor 20 is consistent. Therefore, the ratio of zinc/tin ratio is consistent and is between 1.05 and 1.2, and the formed absorbing layer is mainly a single Kesterite crystal form. Also, the element distribution of the absorbing layer is uniform, and the transformation efficiency of the solar cell is improved.

According to the method for preparing the absorbing layer of the solar cell and the thermal treatment device thereof provided by the embodiments of the disclosure, the solid vapor source inhibits the effusion of the group XIV element of the absorbing layer precursor so that the proportion of the group XIV element in the absorbing layer formed by the absorbing layer precursor is consistent. Therefore, during the preparation process of the absorbing layer of the solar cell, an absorbing layer of a single crystal form is formed, so that the problem that different crystal forms are generated due to the effusion of the element in the absorbing layer is solved. In addition, the element distribution in the absorbing layer, prepared after the solid vapor source is disposed, is uniform, as well the transformation efficiency is improved.

What is claimed is:

1. A method for preparing an absorbing layer of a solar cell, comprising:
providing a substrate, an absorbing layer precursor being loaded on the substrate, and the absorbing layer precursor comprising at least one group XIV element;
providing a solid vapor source, the solid vapor source containing a group XIV element the same as the group XIV element in the absorbing layer precursor, the solid vapor source corresponding to the absorbing layer precursor, and the solid vapor source and the absorbing layer precursor being kept apart by a distance; and
performing a heating process, so that the absorbing layer precursor forming an absorbing layer on the substrate, the solid vapor source being vaporized and generating a gas of the group XIV element, and the gas of the group XIV element inhibiting the effusion of the group XIV element of the absorbing layer precursor so that the proportion of the group XIV element in the formed absorbing layer being consistent.

2. The method for preparing the absorbing layer of the solar cell according to claim 1, wherein the step of providing the solid vapor source further comprises:
providing a base; and
loading a film on the base, the film containing the group XIV element.

3. The method for preparing the absorbing layer of the solar cell according to claim 2, wherein the method for loading the thin film on the base comprises coating, chemical plating, sputtering, or evaporation.

4. The method for preparing the absorbing layer of the solar cell according to claim 1, wherein the reaction temperature of the heating process is 200° C. to 800° C.

5. The method for preparing the absorbing layer of the solar cell according to claim 1, wherein the reaction temperature of the heating process is 350° C. to 650° C.

6. The method for preparing the absorbing layer of the solar cell according to claim 1, wherein the solid vapor source is stannic sulfide, stannic selenide, stannous sulfide, stannous selenide, or the combination thereof.

7. The method for preparing the absorbing layer of the solar cell according to claim 1, further comprising a gas of a group XVI element, the gas of the group XVI element being sulfur vapor, selenium vapor, hydrogen sulfide, hydrogen selenide, or the combination thereof.

8. The method for preparing the absorbing layer of the solar cell according to claim 1, further comprising a gas consisting a group XIV element and a group XVI element, the gas consisting the group XIV element and the group XVI element being stannic sulfide, stannic selenide, stannous sulfide, stannous selenide, or the combination thereof.

9. A thermal treatment device, used for performing thermal treatment on an absorbing layer precursor of a solar cell, the absorbing layer precursor containing at least one group XIV element, the thermal treatment device comprising:
a cavity;
a substrate, disposed in the cavity, and used for bearing the absorbing layer precursor;
a base, disposed in the cavity, and facing the substrate and the absorbing layer precursor; and
a solid vapor source, disposed on the substrate, and containing a group XIV element the same as the group XIV element in the absorbing layer precursor, the solid vapor source facing the absorbing layer precursor;
wherein, the solid vapor source and the base are kept apart by a distance, so that the solid vapor source inhibits the effusion of the group XIV element of the absorbing layer precursor so that the proportion of the group XIV element in an absorbing layer formed by the absorbing layer precursor is consistent.

10. The thermal treatment device according to claim 9, wherein the distance between the solid vapor source and the absorbing layer precursor is 0.1 cm to 4 cm.

11. The thermal treatment device according to claim 9, wherein the distance between the solid vapor source and the absorbing layer precursor is 0.1 cm to 2 cm.

12. The thermal treatment device according to claim 9, wherein the group XIV element is tin.

13. The thermal treatment device according to claim 9, wherein the solid vapor source is stannic sulfide, stannous sulfide, stannic selenide, stannous selenide, or the combination thereof.

14. The thermal treatment device according to claim 9, wherein the cavity is an open cavity.

15. The thermal treatment device according to claim 9, wherein the cavity is a half-open cavity.

16. The thermal treatment device according to claim 9, further comprising a gas of a group XVI element, the gas of the group XVI element being sulfur vapor, selenium vapor, hydrogen sulfide, hydrogen selenide, or the combination thereof.

17. The thermal treatment device according to claim 9, further comprising a gas consisting a group XIV element and a group XVI element, the gas consisting the group XIV element and the group XVI element being stannic sulfide, stannous sulfide, stannic selenide, stannous selenide, or the combination thereof.
